(19) United States
(12) Patent Application Publication
(10) Pub. No.: US 2025/0006769 A1
(43) Pub. Date: Jan. 2, 2025

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventors: SHOGO YAMASAKI, Kanagawa (JP); ATSUSHI FURUBAYASHI, Kanagawa (JP)

(21) Appl. No.: 18/753,882

(22) Filed: Jun. 25, 2024

(30) Foreign Application Priority Data
Jun. 28, 2023 (JP) 2023-105955

(51) Int. Cl. H01L 27/146; H04N 25/707; H04N 25/772

(52) U.S. Cl. CPC H01L 27/14636; H01L 27/14634; H04N 25/707; H04N 25/772

(57) ABSTRACT

A photoelectric conversion device includes first and second semiconductor components. A semiconductor layer of the first semiconductor component includes a pixel array unit. First and second elements are included in a semiconductor layer different from the first semiconductor layer. At a bonding surface, first and second insulating films are bonded, and first and second metal portions are bonded. A first pixel generating a signal corresponding to brightness and the first element are connected through the first metal portion. A second pixel generating an event signal and the second element are connected through a second metal portion. A first conductor included in a first electrical path and positioned in a predetermined layer between first and fourth surfaces is provided, and a second conductor included in a second electrical path and positioned in the predetermined layer is provided. The first and second conductors are different in size.

### BACKGROUND

### Field

The present disclosure generally relates to a photoelectric conversion device. The present disclosure also relates to a photoelectric conversion system and a moving body that include the photoelectric conversion device.

### Description of the Related Art

In a known photoelectric conversion device, a plurality of semiconductor components are laminated together, and a plurality of conductor portions disposed between the plurality of semiconductor components are bonded. A solid-state image capturing element is described in Japanese Patent Laid-Open No. 2022-106021. This solid-state image capturing element includes a light receiving substrate in which a photoelectric conversion element is provided and a circuit board that is bonded to the light receiving substrate and includes an address event detection circuit configured to detect a change in voltage output from the photoelectric conversion element.

In the technique described in Japanese Patent Laid-Open No. 2022-106021, no discussion has been made on forms of electrical paths in the photoelectric conversion device in which pixels generating signals corresponding to brightness of incident light and pixels generating event signals are provided.

### SUMMARY

According to some embodiments of the present disclosure, a photoelectric conversion device includes a first semiconductor component including a first semiconductor layer having a first surface that is a light incident surface and a second surface opposite from the first surface, and a first wiring structure. The photoelectric conversion device also includes a second semiconductor component including a second semiconductor layer having a third surface and a fourth surface opposite from the third surface, and a second wiring structure disposed between the first wiring structure and the third surface. The first semiconductor layer includes a pixel array unit in which a plurality of first pixels and a plurality of second pixels are disposed. Each of the plurality of first pixels is configured to generate a signal corresponding to brightness depending on a light quantity of incident light, and each of the plurality of second pixels is configured to generate an event signal from the incident light. The photoelectric conversion device includes a first element and a second element. Each of the first element and the second element is provided in a semiconductor layer different from the first semiconductor layer. The first wiring structure includes a first insulating film having a recessed portion, and the second wiring structure includes a second insulating film having a recessed portion. The photoelectric conversion device includes a first metal portion provided in the recessed portion of the first insulating film and a second metal portion provided in the recessed portion of the second insulating film. The first insulating film and the second insulating film are bonded to each other at a bonding surface, and the first metal portion and the second metal portion are bonded to each other at the bonding surface. The first pixel and the first element are connected to each other through a first electrical path that passes through the first metal portion. The second pixel and the second element are connected to each other through a second electrical path that passes through the second metal portion. A first conductor and a second conductor are provided. The first conductor is included in the first electrical path and positioned in a predetermined layer between the first surface and the fourth surface, and the second conductor is included in the second electrical path and positioned in the predetermined layer. In plan view with respect to the first surface, a size of the first conductor and a size of the second conductor are different from each other.

Further features of the present disclosure will become apparent from the following description of exemplary embodiments with reference to the attached drawings.

### BRIEF DESCRIPTION OF THE DRAWINGS

FIG. 1 is a block diagram illustrating the entirety of a photoelectric conversion device according to a first embodiment.

FIG. 2 illustrates a configuration of the photoelectric conversion device of a lamination type according to the first embodiment.

FIG. 3 is a sectional view illustrating a section of the photoelectric conversion device illustrated in FIG. 2.

FIGS. 4A and 4B are plan views illustrating structures of bonding portions illustrated in FIG. 3.

FIG. 5 is a sectional view illustrating the structures of the bonding portions illustrated in FIG. 3.

FIG. 6 is a sectional view illustrating structures of another form of the bonding portions illustrated in FIG. 3.

FIG. 7 is a plan view illustrating the structures of the bonding portions illustrated in FIG. 6.

FIG. 8 is an example of a block diagram illustrating a configuration of the photoelectric conversion device according to the first embodiment.

FIG. 9 is another example of a block diagram illustrating a configuration of the photoelectric conversion device according to the first embodiment.

FIG. 10 illustrates a configuration of the photoelectric conversion device of the lamination type according to the first embodiment.

FIG. 11 is a sectional view illustrating a section of the photoelectric conversion device according to a second embodiment.

FIG. 12 is a block diagram illustrating the entirety of the photoelectric conversion device according to a third embodiment.

FIG. 13 is a sectional view illustrating a section of the photoelectric conversion device according to the third embodiment.

FIG. 14 is a plan view illustrating the configuration of a transistor according to the third embodiment.

FIG. 15 is a block diagram illustrating a configuration of a pixel according to a fourth embodiment.

FIGS. 16A to 16C illustrate operation of the pixel according to the fourth embodiment.

FIG. 17 is an example of a laminated sensor including a plurality of semiconductor components according to a fifth embodiment.

FIG. 18 is another example of a laminated sensor including a plurality of semiconductor according to the fifth embodiment.

FIG. 19 is another example of a laminated sensor including a plurality of semiconductor according to the fifth embodiment.

FIG. 20 illustrates a configuration of a photoelectric conversion system according to a sixth embodiment.

FIGS. 21A and 21B illustrate a configuration and operation of a moving body according to a seventh embodiment.

### DESCRIPTION OF THE EMBODIMENTS

The technique of the present disclosure provides forms of electrical paths in a photoelectric conversion device in which pixels generating signals corresponding to brightness of incident light and pixels generating event signals are provided.

Hereinafter, various exemplary embodiments, features, and aspects of the present disclosure will be described with reference to the drawings.

According to each embodiment to be described below, mainly, an image capturing device is described as an example of a photoelectric conversion device. However, each embodiment is not limited to the image capturing device and can also be applied to other examples of the photoelectric conversion device. For example, the embodiment can be applied to a distance measuring device (a device for, for example, measuring a distance using focus detection or time of flight (TOF)), a light measuring device (a device for, for example, measuring an incident light quantity), and the like.

A conductivity type of a transistor to be described according to the embodiments below is merely exemplary, and the conductivity type is not limited to that described in the exemplary embodiments. The conductivity type can be appropriately changed from the conductivity type described in the embodiments, and the potentials of the gate, source, drain of the transistor are appropriately changed in accordance with this change.

For example, in a transistor to be operated as a switch, a low level and a high level of the potential supplied to the gate may be inverted, in accordance with a change in the conductivity type, from those described in the exemplary embodiments. A conductivity type of a semiconductor region to be described in the exemplary embodiments below is merely exemplary, and the conductivity type is not limited to that described in the exemplary embodiments. The conductivity type can be appropriately changed from the conductivity type described in the embodiments, and the potential of the semiconductor region is appropriately changed in accordance with this change.

Furthermore, according to the embodiments below, connection between elements of a circuit may be described. In this case, even when a different element is interposed between the elements of interest, the elements of interest are interpreted as elements electrically connected to each other unless otherwise specified. For example, it is assumed that an element A is connected to one node of a capacitor element C including a plurality of nodes and an element B is connected to the other node of the capacitor element C.

Even in such a case, the element A and the element B are interpreted as elements electrically connected to each other unless otherwise stated. When elements are connected to each other without a different component interposed therebetween, this connection may be expressed as being directly connected. In the above-described example, when a different element is not provided between the element A and the capacitor element C, it can be said that the element A and the capacitor element C are directly connected to each other.

Regarding metal members such as wiring and pads described herein, each type of the metal members may only include metal of a single element or may be a mixture (alloy). For example, wiring described as copper wiring may only include copper or mainly include copper and further include another element than copper. For example, pads to be connected to external terminals may only include aluminum or mainly include aluminum and further include another element (for example, copper) than aluminum. The copper wiring and the aluminum pads described herein are merely exemplary and the types of metal can be changed to various other types of metal.

The wiring and the pads described herein are examples of the metal members used in the photoelectric conversion device and may also be applied to other metal members.

Hereinafter, the embodiments are described with reference to the drawings.

### First Embodiment

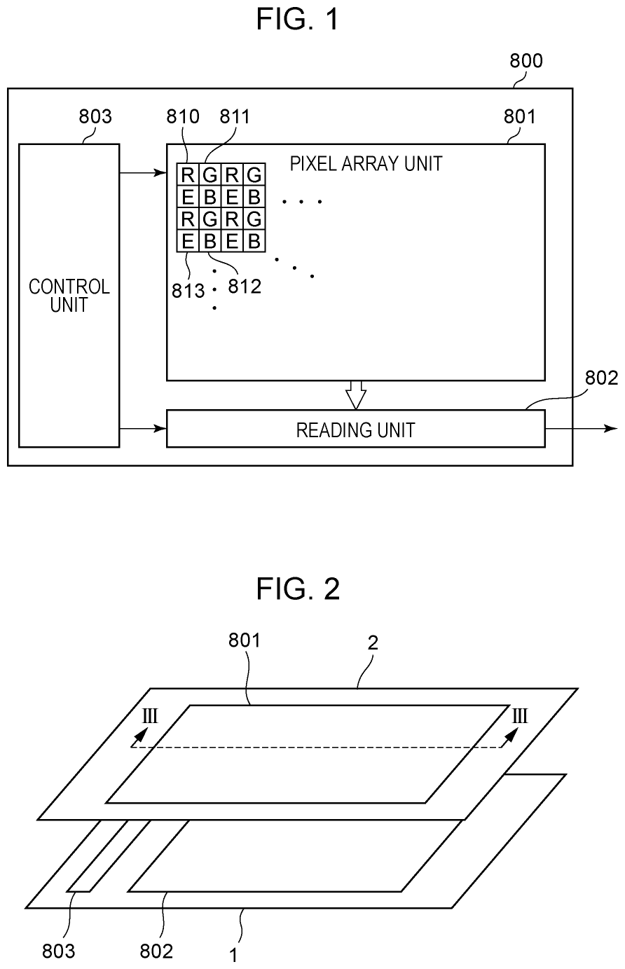

FIG. 1 is a block diagram of a photoelectric conversion device according to a first embodiment.

A photoelectric conversion device 800 includes a pixel array unit 801, a reading unit 802, and a control unit 803. The pixel array unit 801 includes R pixels 810, G pixels 811, and B pixels 812. The R pixels 810, the G pixels 811, and the B pixels 812 are first pixels that are configured to generate signals respectively corresponding to brightnesses of incident light. The R pixels are the first pixels upon which light transmitted through a color filter corresponding to red is incident. The G pixels are the first pixels upon which light transmitted through a color filter corresponding to green is incident. The B pixels are the first pixels upon which light transmitted through a color filter corresponding to blue is incident. Hereinafter, the pixels generating the signals corresponding to the brightnesses may be referred to as brightness pixels.

The pixel array unit 801 also includes event detection pixels 813 that are second pixels configured to generate event signals. Regarding the first pixels and the second pixels, three first pixels (an R pixel 810, a G pixel 811, and a B pixel 812) and a single second pixel are included in an array of two rows and 2 columns. The pixel array unit 801 has a configuration in which arrays of two rows and two columns are periodically disposed. Although no light-shielded pixel is provided in the pixel array unit 801, the pixel array unit 801 may include a light-shielded pixel. The light-shielded pixel may be configured such that a pixel configuration of the light-shielded pixel is the same as that of each of the R pixel 810, the G pixel 811, and the B pixel 812, and a photoelectric conversion unit provided in each of the R pixel 810, G pixel 811, B pixel 812 is shielded from the light. Furthermore, a light-shielded pixel which has the same pixel configuration as that of the event detection pixel 813 and in which the photoelectric conversion unit of the event detection pixel 813 is shielded from the light may be included. Furthermore, a pixel without a color filter (white pixel) may be provided. The color filters of R, G, B are exemplary. Color filters of complementary colors may be provided. That is, color filters of cyan, magenta, and yellow may be disposed.

The reading unit 802 is configured to perform various processes on the signals output from the pixel array unit 801. Examples of the various processes include an analog-to-digital conversion process, a correlated double sampling process, a process of adding the signals of a plurality of pixels to each other, a signal correction process, and so forth.

The control unit 803 may include one or more processors, circuitry, or combinations thereof, and controls reading of the pixels of the pixel array unit 801. The control unit 803 controls the first pixels on the pixel row basis, thereby to perform vertical scanning in which the signals are read from the corresponding first pixels. Furthermore, the control unit 803 includes an arbitration circuit that sequentially selects the second pixels is which events are detected out of a plurality of second pixels. Thus, event signals are read to the reading unit 802 sequentially from the plurality of second pixels. That is, the arbitration circuit performs control in which the sequence of reading from the plurality of second pixels where the events are detected is arbitrated.

FIG. 2 illustrates a configuration of the photoelectric conversion device according to the present embodiment. The photoelectric conversion device according to the present embodiment has a structure of a laminated sensor in which a semiconductor component 1 and a semiconductor component 2 are laminated together. The reading unit 802 and the control unit 803 illustrated in FIG. 1 are provided in the semiconductor component 1. The pixel array unit 801 illustrated in FIG. 1 is provided in the semiconductor component 2. Although a structure in which two semiconductor components are laminated together is described herein, another semiconductor component may be further laminated together. In this case, one part of the reading unit 802 may be disposed in one of the semiconductor components, and the other part of the reading unit 802 may be disposed in the other semiconductor component. In this case, as the one part of the reading unit 802, a circuit processing the signals of the plurality of first pixels (signals corresponding to the brightness) may be disposed in the one semiconductor component, and, as the other part of the reading unit 802, a circuit processing the signals of the plurality of second pixels (event detection signals) is disposed in the other semiconductor component.

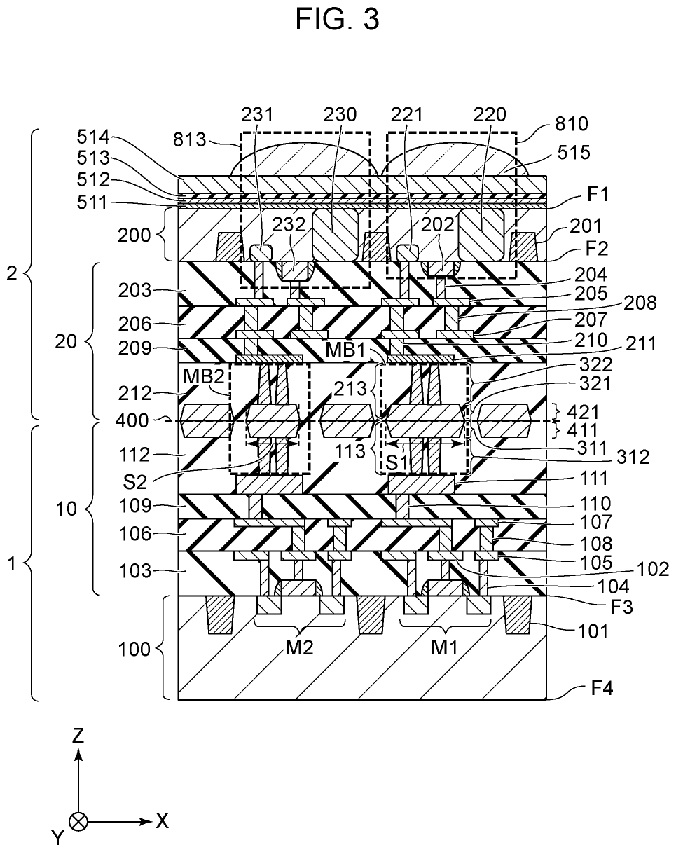

FIG. 3 is a sectional view corresponding to part of a section of the photoelectric conversion device illustrated in FIG. 2 taken along line III-III illustrated in FIG. 2.

The semiconductor component 1 includes a semiconductor layer 100 and a wiring structure 10 (a second wiring structure). Metal oxide semiconductor (MOS) transistors M1 and M2, which are elements included in the reading unit 802 or the control unit 803, and element isolation portions 101 are provided in the semiconductor layer 100. Typically, the semiconductor layer 100 is a semiconductor substrate. Typically, the semiconductor substrate is formed of single-crystal silicon and has a thickness of 100 to 800 μm. The MOS transistor M1 is a first element included in the semiconductor layer 100. The MOS transistor M2 is a second element included in the semiconductor layer 100. The semiconductor layer 100 may be a chemical-compound semiconductor substrate such as a GaAs substrate.

The wiring structure 10 includes interlayer insulating films 103, 106, and 109 and an insulating film 112. Wiring layers 105, 107, and 111 are provided corresponding to layers of the interlayer insulating films 103, 106, and 109. Each of the interlayer insulating films 103, 106, and 109 typically includes a silicon oxide film (an SiO₂ film) and a silicon carbide film (an SiC film). The interlayer insulating film 103, 106, or 109 does not necessarily include these materials. Each of the interlayer insulating films 103, 106, and 109 may be a film including a silicon nitride film (an Si₃N₄ film) or a silicon oxynitride film (an SiₓO_{y}N_{z} film; x, y, and z are arbitrary values). Wiring included in each of the wiring layers 105 and 107 is copper wiring. Wiring included in the wiring layer 111 is aluminum wiring. Via plugs 108 and 110 that interconnect the wiring layers and contact plugs 104 are provided in the interlayer insulating films 103, 106, and 109. The contact plugs 104 are formed of tungsten. The via plugs 108 are formed of copper. The wiring of the wiring layer 107 and the via plugs 108 are integrally formed through a dual damascene process. The via plugs 110 are formed of tungsten.

Furthermore, vias 312 and bonding members 311 are provided in the insulating film 112 (a second insulating film). The bonding members 311 are provided in recessed portions formed in the insulating film 112. The vias 312 and the bonding members 311 include copper. Furthermore, the bonding members 311 and the vias 312 are integrally formed through the dual damascene process. Although it is not illustrated, the copper wiring of the wiring layer 105, the copper wiring of the wiring layer 107, the via plugs 108, the vias 312, and the bonding members 311 may be provided with respective barrier metals disposed at respective outer peripheries. The barrier metals can be formed of one of titanium (Ti), titanium nitride (TiN), tntalum (Ta), tantalum nitride, and tungsten (W), or an alloy formed by combining a plurality of these. This can suppress diffusion of the copper from the copper wiring of the wiring layer 105, the copper wiring of the wiring layer 107, the via plugs 108, the vias 312, and bonding members 411. The bonding members 411 not connected to the vias are further disposed in the insulating film 112. The bonding members 411 may be electrically floating.

The semiconductor component 2 includes a semiconductor layer 200 and a wiring structure 20 (a first wiring structure).

A photodiode 230 included in the event detection pixel 813 being one of the second pixels, a semiconductor region 231, and a gate electrode 232 are provided in the semiconductor layer 200. The semiconductor region 231 is one of the source and drain of the MOS transistor being the second element included in the second pixel. The MOS transistor including the illustrated gate electrode 232 and the semiconductor region 231 is a signal output transistor included in the R pixel 810 and is not necessarily a transfer transistor.

Furthermore, a photodiode 220 including the R pixel 810 being one of the first pixel, a semiconductor region 221, and a gate electrode 222 are provided in the semiconductor layer 200. The semiconductor region 221 is one of the source and drain of the MOS transistor being the first element included in the first pixel. The MOS transistor including the illustrated gate electrode 222 and the semiconductor region 221 is a signal output transistor included in the R pixel 810 and is not necessarily a transfer transistor.

Light is incident upon each of the photodiodes 220 and 230 through optical members. The optical members include micro-lenses 515 and a color filter layer 514. Color filters corresponding to colors that differ depending on the pixels as illustrated in FIG. 1 are provided in the color filter layer 514. A metal oxide film 511, an anti-reflection film 512, and an insulating film 513 are provided between the color filter layer 514 and the semiconductor layer 200. The metal oxide film 511 can be a fixed charge film (a pinning film) having a negative fixed charge. For example, the metal oxide film 511 can be aluminum oxide (an Al₂O₃ film). When the metal oxide film 511 is provided, a dark current component in the semiconductor layer 200 can be reduced. The anti-reflection film 512 can be, for example, a tantalum oxide film. The insulating film 513 can be, for example, a silicon oxide film and may further include a film formed of another material (a silicon nitride film, a silicon oxynitride film, or the like).

The semiconductor layer 200 includes a first surface F1 and a second surface F2. The first surface F1 is an incident surface upon which the light is incident. The second surface F2 is an opposite surface from the first surface F1. The gate electrodes of the transistors are provided in the second surface F2.

The semiconductor layer 100 includes a third surface F3 and a fourth surface F4 being an opposite surface from the third surface F3. The wiring structure 10 and the wiring structure 20 are provided between the third surface F3 and the second surface F2. The wiring structure 20 is provided between the wiring structure 10 and the third surface F3.

Furthermore, element isolation portions 201 are provided in the semiconductor layer 200. The element isolation portions 201 have a structure of shallow trench isolation (STI). However, this example is not limiting. The element isolation portions 201 may have a structure of deep trench isolation (DTI) or a structure of local oxidation of silicon (LOCOS). Typically, the semiconductor layer 200 is a semiconductor substrate.

Typically, the semiconductor substrate is formed of single-crystal silicon and has a thickness of 1 to 10 μm (micrometer). The semiconductor layer 200 may be a chemical-compound semiconductor substrate such as a GaAs substrate. In the semiconductor layer 200, a single-crystal such as germanium may be further disposed on the incident surface of a layer formed of the single crystal. This configuration can further improve the sensitivity to ultrared light. The germanium may be used as an intrinsic semiconductor or may be an impurity semiconductor doped with an impurity such as phosphorus (P), arsenic (As), antimony (Sb), boron (B), aluminum (Al), or gallium (Ga). The germanium is only an example. A material having a different band gap from silicon can be used. For example, indium gallium arsenide (InGaAs) or germanium-tin (GeSn) may be used.

The wiring structure 20 includes interlayer insulating films 203, 206, and 209 and an insulating film 212. Wiring layers 205, 207, and 211 are provided corresponding to the interlayer insulating films 203, 206, and 209, respectively. Each of the interlayer insulating films 203, 206, and 209 typically includes a silicon oxide film (an SiO₂ film) and a silicon carbide film (an SiC film). The interlayer insulating film 203, 206, or 209 does not necessarily include these materials. Each of the interlayer insulating films 203, 206, and 209 may be a film including a silicon nitride film (an Si₃N₄ film) or a silicon oxynitride film (an SiₓO_{y}N_{z} film; x, y, and z are arbitrary values). Wiring included in each of the wiring layers 205, 207, and 211 is copper wiring. Via plugs 208 and 210 that interconnect the wiring layers and contact plugs 204 are provided in the interlayer insulating films 203, 206, and 209. The contact plugs 204 are formed of tungsten. The via plugs 208 and 210 are formed of copper. The wiring of the wiring layer 207 and the via plugs 208 are integrally formed through the dual damascene process. Likewise, the wiring of the wiring layer 211 and the via plugs 210 are integrally formed through the dual damascene process.

Furthermore, vias 322 and bonding members 321 are provided in the insulating film 212 (a first insulating film). The bonding members 321 are provided in recessed portions formed in the insulating film 212. The vias 322 and the bonding members 321 include copper. Furthermore, the bonding members 321 and the vias 322 are integrally formed through the dual damascene process. Although it is not illustrated, the copper wiring of the wiring layer 205, the copper wiring of the wiring layer 207, the copper wiring of the wiring layer 211, the via plugs 208, the vias 322, and the bonding members 321 may be provided with respective barrier metals disposed at respective outer peripheries.

The barrier metals can be formed of one of titanium (Ti), titanium nitride (TiN), tantalum (Ta), tantalum nitride, and tungsten (W), or an alloy formed by combining a plurality of these. This can suppress diffusion of the copper from the copper wiring of the wiring layer 205, the copper wiring of the wiring layer 207, the copper wiring of the wiring layer 211, the via plugs 208, the vias 322, and the bonding members 421. The bonding members 421 not connected to the vias are also disposed in the insulating film 212. The bonding members 421 may be electrically floating. The vias may be connected either the bonding members 411 or the bonding members 421 so as to provide a predetermined potential. In this case, the vias are not connected to the other bonding members.

The semiconductor component 1 and the semiconductor component 2 are bonded to each other at a bonding surface 400. Regarding bonding at the bonding surface 400, the insulating films are bonded together. That is, the insulating film 112 and the insulating film 212 are bonded together. Also, the metal members are bonded together. That is, the bonding members 411 and the bonding members 421 are bonded together, and the bonding members 311 and the bonding members 321 are bonded together. The bonding as described above in which the insulating films are bonded together and the metal members are bonded together in a single plane is also called as hybrid bonding. Bonding portions of metal members include a bonding portion MB1 through which the signal output from the first pixels is transmitted and a bonding portion MB2 through which the signal output from the second pixels is transmitted. The R pixel 810 being one of the first pixels and the MOS transistor M1 being the first element included in the semiconductor layer 100 are connected to each other through a first electrical path that passes through the bonding portion MB1 being a first metal portion. The first electrical path includes the wiring layers 105, 107, 111, 205, 207, and 211 and the via plugs connecting the wiring layers. The event detection pixel 813 being one of the second pixels and the MOS transistor M2 being the second element included in the semiconductor layer 100 are connected to each other through a second electrical path that passes through the bonding portion MB2 being a second metal portion.

The second electrical path includes the wiring layers 105, 107, 111, 205, 207, and 211 and the via plugs connecting the wiring layers.

In the configuration illustrated in FIG. 3, a width S1 of the bonding portion MB1 through which the signal of the second pixel is transmitted is greater than a width S2 of the bonding portion MB2 through which the signal of the first pixel is transmitted.

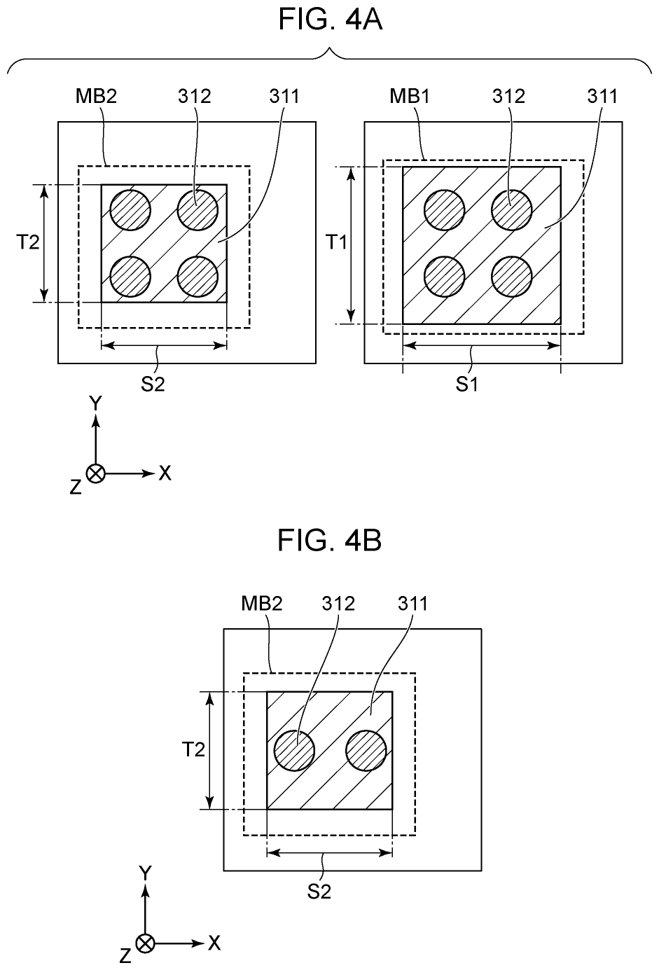

FIGS. 4A and 4B illustrate structures of the bonding members 311 in plan view seen from the top surface of the first surface F1 being a light incident surface. Out of the reference numerals presented in FIGS. 4A and 4B, reference numerals also presented in FIG. 3 are in corresponding relationships with each other.

FIG. 4A is a plan view illustrating structures, in plan view, of the bonding member 311 included in the bonding portion MB1 illustrated in FIG. 3 and the bonding member 311 included in the bonding portion MB2. The width S1 and the width S2 illustrated in FIG. 4A correspond to the width S1 and the width S2 illustrated in FIG. 3. Each of the width S1 and the width S2 is the length in the X direction in FIG. 4A that is a first direction. Both the bonding member 311 of the bonding portion MB1 and the bonding member 311 of the bonding portion MB2 are disposed in a predetermined layer positioned at a predetermined depth from the second surface F2 of the semiconductor layer 200.

Furthermore, the bonding member 311 included in the bonding portion MB1 has the length of a width T1 being the length in the Y direction in FIG. 4A that is a second direction. Furthermore, the bonding member 311 included in the bonding portion MB2 has the length of a width T2 being the length in the Y direction in FIG. 4A that is the second direction. The width T1 is greater than the width T2. That is, the following relationships hold: S2<S1 and T2<T1. Alternatively, the following relationship may hold: S1=T1 or S2=T2, or the following relationships may hold: S1/T1 and S2/T2. That is, it is sufficient that the bonding member 311 of the bonding portion MB1 and the bonding member 311 of the bonding portion MB2 be different in at least one of the width and the length. The size of the bonding members 311 includes the length and the width. The size may further include the thickness. In this case, the thickness may vary between the bonding member 311 of the bonding portion MB1 and the bonding member 311 of the bonding portion MB2 while the bonding member 311 of the bonding portion MB1 and the bonding member 311 of the bonding portion MB2 have the same length and width. The size limited to the length and the width may be referred to as planar size. The relationships between the area of the bonding member 311 of the bonding portion MB2 and the area of the bonding member 311 of the bonding portion MB1 are as follows: S2×T2<S1×T1. When these relationships hold, the resistance of the bonding portion MB2 can be smaller than the resistance of the bonding portion MB1.

Furthermore, referring to FIG. 4A, four vias 312 are connected to each of the bonding member 311 of the bonding portion MB1 and the bonding member 311 of the bonding portion MB2. Referring to FIG. 4B, the number of vias 312 connected to the bonding member 311 is reduced to two in the bonding portion MB2. With this configuration, the size of the bonding portion MB2 can be further reduced. Although the structures related to the bonding members 311 and the vias 312 have been described with reference to FIGS. 4A and 4B, the bonding members 321 and the vias 322 may have the same structures as those of the bonding members 311 and the vias 312.

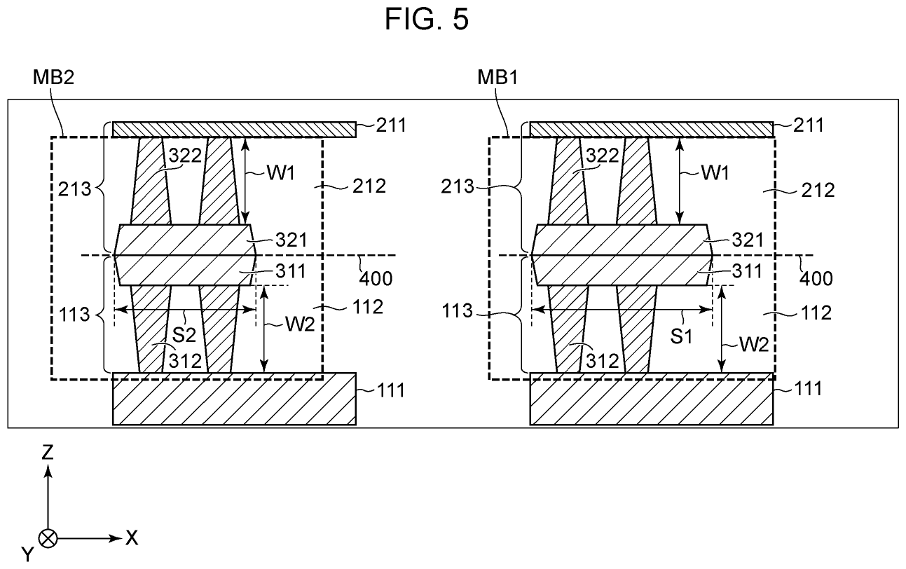

FIG. 5 is an enlarged sectional view of regions near the bonding portions MB1 and MB2 illustrated in FIG. 3. A length W1 of the vias 322 is smaller than a length W2 of the vias 312. In contrast, the length of the vias 312 is the same length W1 in both the bonding portion MB1 and the bonding portion MB2. Also, the length of the vias 322 is the same length W2 in both the bonding portion MB1 and the bonding portion MB2. With this structure, the bonding portion MB1 and the bonding portion MB2 can be simultaneously formed. Meanwhile, from a different viewpoint, from the viewpoint of ease of the manufacture, varying the length of the vias 312 and the vias 322 between the bonding portion MB1 and the bonding portion MB2 can lead to an increase in steps of the manufacturing process. Accordingly, to vary the resistance between the bonding portions MB1 and MB2, the size or the planar size can vary between the bonding members 311 and 321 instead of varying the length of the vias.

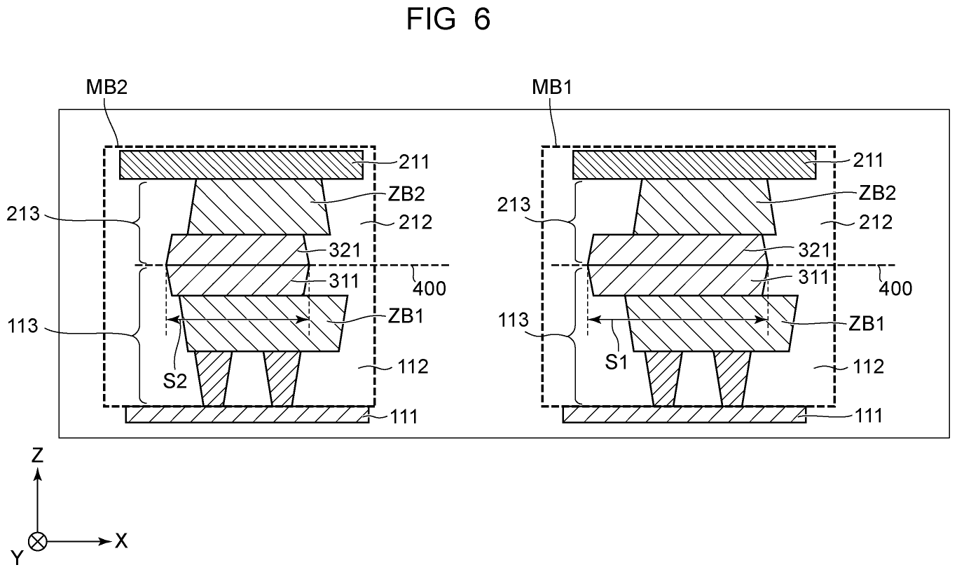

FIG. 6 illustrates another form of the bonding portions. Referring to FIG. 5, the vias are connected to each of the bonding members 311 and 321. In the form illustrated in FIG. 6, auxiliary bonding portions ZB1 and ZB2 are respectively provided for the bonding members 311 and 321.

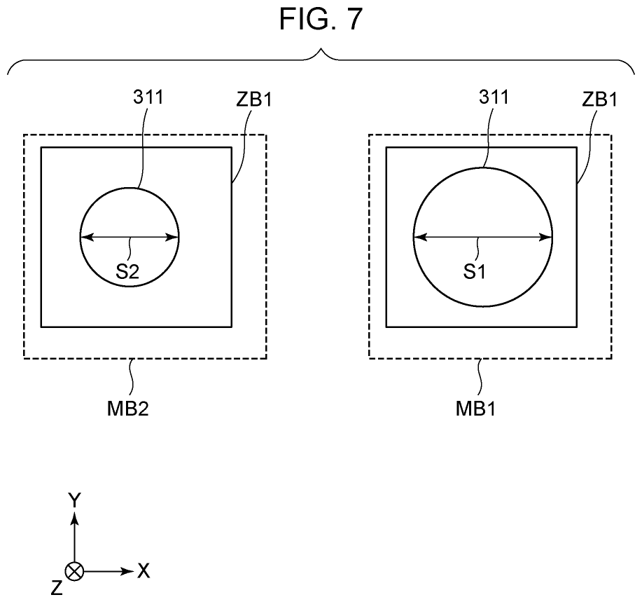

FIG. 7 is a plan view illustrating a structure related to the bonding portions MB1 and MB2 illustrated in FIG. 6 in plan view with respect to the first surface F1 being the light incident surface.

The bonding members 311 have circular shapes in the structures illustrated in FIGS. 6 and 7. The width S1 of the bonding member 311 of the bonding portion MB1 and the width S2 the bonding member 311 of the bonding portion MB2 are respectively the diameter of the bonding member 311 of the bonding portion MB1 and the diameter of the bonding member 311 of the bonding portion MB2. Also, the sizes of the bonding members 311 in this case are the diameters of the bonding members 311 of the bonding portion MB1 and the bonding portion MB2. As described above, the size may include the thickness of the bonding members 311. The areas of the bonding members 311 are given as follows: S1×S1×(¼)×π in the bonding portion MB1; and S2× S2×(¼)×π in the bonding portion MB2. Although it is assumed that the shapes of the bonding members 311 are perfect circles herein, the bonding members 311 may have elliptic shapes. In this case, the size of the bonding members includes the length of a semi-major axis and the length of a semi-minor axis. That is, at least one of the length of the semi-major axis and the length of the semi-minor axis may vary between the bonding member of the bonding portion MB1 and the bonding member of the bonding portion MB2. When the bonding member 311 has the elliptic shape, the area of the bonding member 311 can be given by the following expression: length of semi-major axis×length of semi-minor axis×π. Regardless of whether the shape of the bonding members 311 is a perfect circle or an ellipse, it is sufficient that the size or the planar size vary between the bonding portion MB1 and the bonding portion MB2. Furthermore, regarding the area of the bonding member 311, it is sufficient that the following relationship hold: bonding portion MB1>bonding portion MB2.

Furthermore, according to the present embodiment, the description has been made for the structure related to the electrical path connected to the R pixel 810 being one of the brightness pixels configured to output the signals corresponding to the brightness, the structures related to the electrical paths respectively connected to the G pixel 811 and the B pixel 812 can be the same. Hereinafter, although the description of the specification focuses on the R pixel 810, this structure can be also applied to the G pixel 811 and the B pixel 812.

In contrast, the auxiliary bonding portions ZB1 and ZB2 have rectangular shapes. With this structure, an appropriate force can be applied to a bonding surface of each of the bonding portions MB1 and MB2, and accordingly, bonding can be formed with higher accuracy.

Although the wiring of the wiring layer 111 is aluminum wiring in the form illustrated in FIGS. 3 and 5, the wiring of the wiring layer 111 is not limited to this example and may be copper wiring.

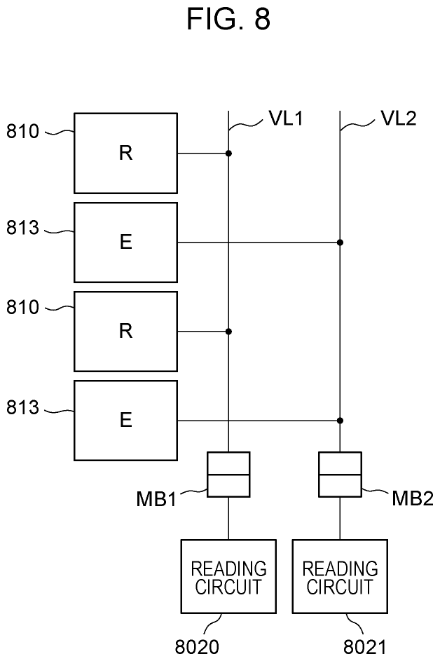

FIG. 8 is an example of a circuit block diagram of the photoelectric conversion device according to the present embodiment. FIG. 8 illustrates a configuration related to the pixels in a single column out of the pixel array unit illustrated in FIG. 1. A signal line VL1 is connected to a plurality of R pixels 810 each of which is the brightness pixel. A signal line VL2 is connected to a plurality of event detection pixels 813. The signal line VL1 is connected to a reading circuit 8020 included in the reading unit 802 through the bonding portion MB1. Also, the signal line VL2 is connected to a reading circuit 8021 included in the reading unit 802 through the bonding portion MB2. In the above-described structure, when the size of the bonding portion MB2 is smaller than the size of the bonding portion MB1, the parasitic capacitance component associated with the bonding portion MB2 can be reduced. This can increase the speed of change in signal in the signal line VL2. Accordingly, the signal of the event detection pixels 813 can be read at high speed, and the event detection can be performed at higher speed. Also with this structure, the maximum amplitude of the output signal of the event detection pixels 813 can be made to be smaller than the maximum amplitude of the output signal of the brightness pixels. When the parasitic capacitance component is reduced by reducing the size of the bonding portion MB2, delay in response and attenuation of the output signal can be reduced, and accordingly, the maximum amplitude can be reduced. Thus, power consumption of the event detection pixels 813 can be reduced.

However, this form is merely exemplary. For example, when the size of the bonding portion MB1 is greater than the size of the bonding portion MB2, the following situation may occur: a speed of change in signal in the signal line VL1 is increased due to reduction of the resistance. Such a configuration produces an effect in which the signals of the brightness pixels can be read at high speed.

The reading circuit 8020 can perform the correlated double sampling process, an amplification process, the analog-to-digital conversion process, and the like on the signals output by the brightness pixels.

The reading circuit 8021 can function as an event detection circuit. The event detection circuit has the function of detecting whether an event occurs by comparing a pixel value of the event detection pixel 813 at a predetermined time and a pixel value of the event detection pixel 813 before the predetermined time.

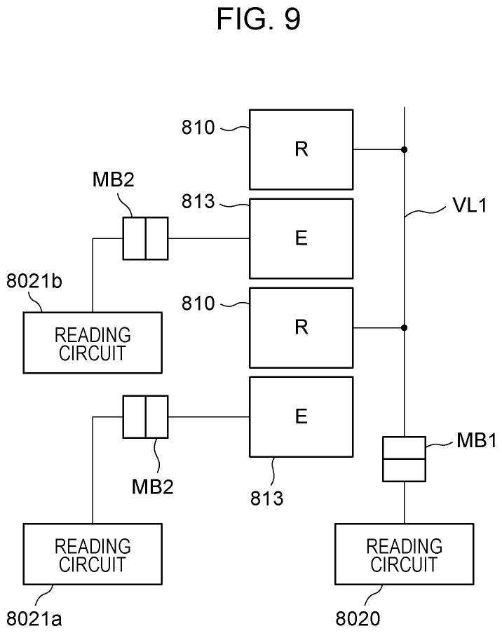

FIG. 9 illustrates another example of the circuit block diagram. The configuration illustrated in FIG. 9 is a form in which bonding portions MB2 are each connected to a corresponding one of the event detection pixels 813. Also in this form, a reading circuit 8021a and a reading circuit 8021b are respectively connected to a plurality of bonding portions MB2. Each of the reading circuit 8021a and the reading circuit 8021b can function as the event detection circuit.

In the form illustrated in FIG. 9, the bonding portions disposed corresponding to a single pixel column are provided such that the number of the bonding portions MB2 corresponding to the event detection pixels 813 is greater than the number of bonding portions MB1 corresponding to the brightness pixels. Reducing the area of the bonding portions MB2 connected to the event detection pixels 813 can improve versatility of the disposition of the bonding portions MB1. From a different viewpoint, a greater number of the bonding portions MB2 can be provided than in the case where the area of the bonding portion MB2 is the same as the area of the bonding portion MB1. Accordingly, the number of the signals of the event detection pixels 813 to be read in parallel can be increased. That is, the signals corresponding to the plurality of event detection pixels 813 can be read at high speed.

Although a single bonding portion MB2 is provided for a single event detection pixel 813 in the configuration illustrated in FIG. 9, this disposition is not limiting. For example, the plurality of event detection pixels 813 positioned on the same column may share a single bonding portion MB2. Alternatively, a plurality of event detection pixels 813 positioned on the same row may share a single bonding portion MB2. Furthermore, a plurality of event detection pixels 813 positioned on a plurality of rows and a plurality of columns may share a single bonding portion MB2.

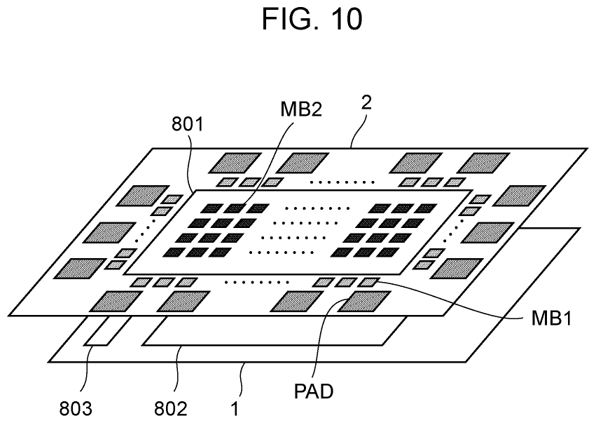

Furthermore, it becomes easy to dispose, in a region inside the pixel array unit 801 illustrated in FIG. 2, the bonding portions MB2 connected to the event detection pixels 813 in plan view with respect to the first surface F1 being the light incident surface. FIG. 10 illustrates an example of the disposition. Referring to FIG. 10, the bonding portions MB2 are disposed in the pixel array unit 801 in plan view with respect to the first surface F1 being the light incident surface. In particular, since the bonding portions MB2 are provided corresponding to the respective event detection pixels 813 in the form of the circuit block diagram illustrated in FIG. 9, the bonding portions MB2 can be disposed in the region inside the pixel array unit 801. However, in the case of disposition inside the pixel array unit 801, the pitch for disposing the bonding portions MB2 is constrained by the pitch of the pixels. According to the present embodiment, since the area of the bonding portions MB2 connected to the event detection pixels is reduced, the bonding portions MB2 can be disposed even when the pitch of the pixels is narrowed. In contrast, as illustrated in FIG. 10, the bonding portions MB1 can be disposed outside the region of the pixel array unit 801. Furthermore, the pads for connection to the outside of the photoelectric conversion device may be provided in the semiconductor component 1 or the semiconductor component 2. The pads can be provided for outputting the signals of the photoelectric conversion device, for supplying power source voltages (VDD, GND, and the like) to the photoelectric conversion device, or for inputting signals such as clock signals and control signals to the photoelectric conversion device. Such pads are provided in the semiconductor component 1 or at an outer peripheral portion of the semiconductor component. FIG. 10 illustrates an example in which the pads PAD are provided in the semiconductor component 2. However, the pads PAD may be provided in the semiconductor component 1. When the pads PAD are provided in the semiconductor component 1, typically, pad openings are provided in the semiconductor component 2 for electrical connection to the pads provided in the semiconductor component 1. Regardless of whether the pads are provided in the semiconductor component 1 or the semiconductor component 2, the bonding portions MB1 are disposed between the pads and an outer periphery of the pixel array unit 801 in plan view with respect to the first surface F1. Referring to FIG. 10, the bonding portions MB1 are provided between the pads PAD provided in the semiconductor component 2 and the outer periphery of the pixel array unit 801. Such disposition can improve versatility of a layout of the disposition of the bonding portions MB2 to be connected to the event detection pixels. The pads PAD described herein can mainly include aluminum. Typically, the pads can mainly include aluminum and also include a small amount of copper. An example of the outer periphery of the pixel array unit 801 may include a region where light-shielded pixels, which are provided outside an opening region upon which the light is incident, are disposed. In this case, the outer periphery can be end portions of the region where the light-shielded pixels are disposed. The pads may be provided on the first surface F1 illustrated in FIG. 3 or in a region closer to the micro-lenses 515 than the first surface F1. The pads may be provided in a groove that is provided in the semiconductor layer 100 from the fourth surface F4 side illustrated in FIG. 3.

Furthermore, regarding the disposition of the bonding portions MB1 illustrated in FIG. 10, it can also be said that the bonding portions MB1 are provided between the pads PAD and an outer periphery of the opening region upon which the light is incident. The opening region may be the entirety of the pixel array unit 801 illustrated in FIG. 10. Alternatively, part of the pixel array unit 801 can be the opening region and the other part of the pixel array unit 801 can be the region where the light-shielded pixels are provided.

Although a single signal line is provided for a single column of the brightness pixels in the described example, more signal lines may be provided.

According to the present embodiment, the area of the bonding portions included in the electrical path connected to the event detection pixels 813 is smaller than the area of the bonding portions included in the electrical path connected to the brightness pixels 810 to 812 that generate the signals corresponding to the brightness. As described above, this produces an effect in which the signals of the event detection pixels 813 can be read at high speed.

According to the present embodiment, the signals output by the first pixels and the second pixels are transmitted through the bonding portions MB1 and MB2 in the described example.

However, this example is not limiting. Signals controlling the first pixels and the second pixels may be transmitted through the bonding portions MB1 and MB2. The signals controlling the first pixels and the second pixels refer to reset operations of the photoelectric conversion unit and input nodes of an output transistor performing signal output, selection operations that cause signals to be output on the pixel row basis, and the like. Also in this case, an effect in which the second pixels can be controlled at high speed is produced.

Although the sizes or the planar sizes of the respective bonding members 311 of the bonding portions MB1 and MB2 are compared according to the present embodiment, the sizes or the planar sizes of the bonding members 321 may be compared.

### Second Embodiment

A second embodiment is described, focusing on the difference from the first embodiment. According to the present embodiment, the area of the bonding portions MB1 connected to the brightness pixels is smaller than the area of the bonding portions MB2 connected to the event detection pixels.

The configuration of the photoelectric conversion device can be the same as that illustrated in FIGS. 1 and 2 described according to the first embodiment.

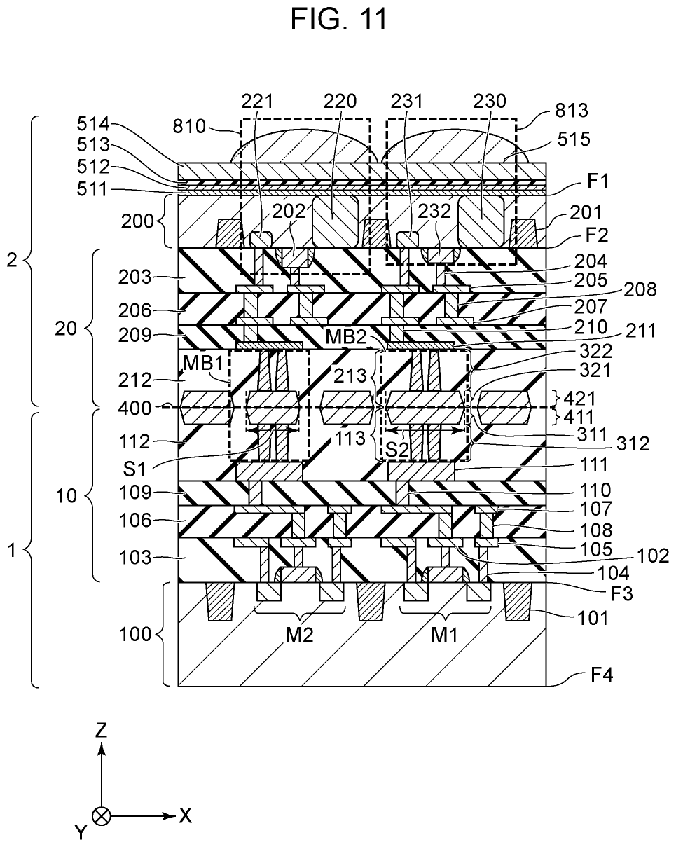

FIG. 11 is a sectional view of the photoelectric conversion device according to the present embodiment. Members having the same functions as those of the members illustrated in FIG. 3 are denoted, in FIG. 11, by the same reference numerals as those of FIG. 3.

According to the present embodiment, the width S1 of the bonding member 311 of the bonding portion MB1 connected to the R pixels 810 being the brightness pixels is smaller than the width S2 of the bonding members 311 of the bonding portions MB2 connected to the event detection pixels 813. Other configurations are the same as the configurations illustrated in FIG. 3 according to the first embodiment.

The structures illustrated in FIGS. 4A, 4B, 5, 6, and 7 described according to the first embodiment can be applied to the present embodiment. In applying these structures, the relationship between the bonding portions MB1 and MB2, which has been described as MB1<MB2 according to the first embodiment, may be reversed for the application to the present embodiment. The bonding portion having the structure illustrated in FIG. 4B, which is the bonding portion MB2 according to the first embodiment, may be the bonding portion MB1 according to the present embodiment.

Furthermore, according to the present embodiment, the circuit block structures respectively illustrated in FIGS. 8 and 9 described according to the first embodiment can be applied.

According to the present embodiment, the area of the bonding portions MB2 connected to the brightness pixels is smaller than the area of the bonding portions MB1 connected to the event detection pixels. Thus, the signals of the brightness pixels can be read at higher speed. This can realize one or both of an increase in resolution and an increase in frame rate of images for which the signals of the brightness pixels are used.

### Third Embodiment

A third embodiment is described, focusing on the difference from the first embodiment.

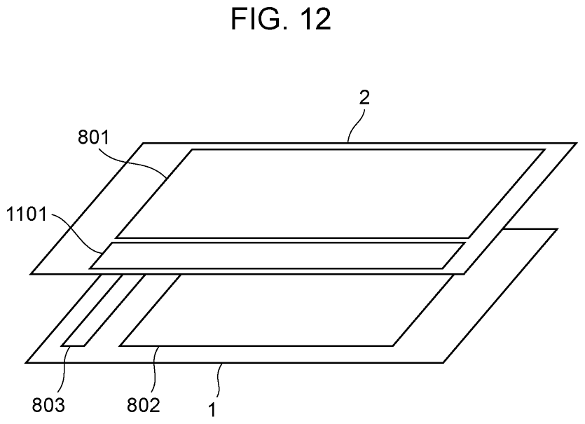

FIG. 12 is a circuit block diagram of the photoelectric conversion device according to the present embodiment. According to the present embodiment, the semiconductor component 2 includes an analog-to-digital (AD) conversion circuit 1101. The AD conversion circuit 1101 performs an AD conversion on the signals output by the brightness pixels.

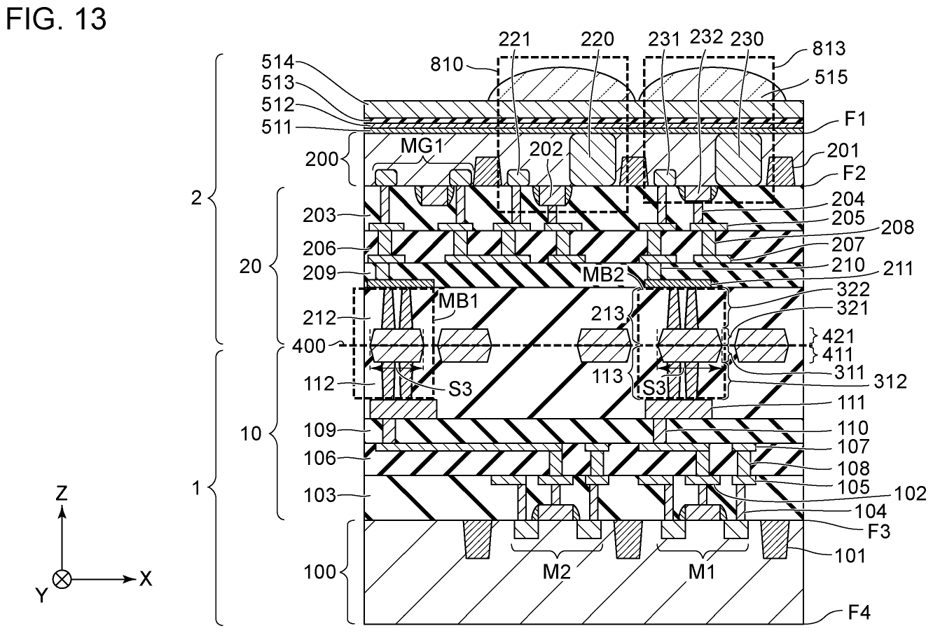

FIG. 13 is a sectional view of the photoelectric conversion device according to the present embodiment. Members having the same functions as those of the members illustrated in FIG. 3 are denoted, in FIG. 13, by the same reference numerals as those of FIG. 3.

The configuration illustrated in FIG. 13 indicates a transistor group MG1 included in the AD conversion circuit 1101 illustrated in FIG. 12. Typically, the transistor group MG1 includes a plurality of transistors.

Regarding the bonding portion MB1, digital signals output by the transistor group MG1 are output, through the bonding portion MB1, to the transistor M2 provided in the semiconductor layer 100. Both the bonding portion MB1 and the bonding portion MB2 have the same width S3. Although the length in the depth direction is not illustrated, according to the present embodiment, the area of the bonding member 321 included in the bonding portion MB1 and the area of the bonding member 321 included in the bonding portion MB2 are the same, and the area of the bonding member 311 included in the bonding portion MB1 and the area of the bonding member 311 included in the bonding portion MB2 are the same.

According to the present embodiment, the planar size (gate lengths, gate widths) varies between the MOS transistor connected to the bonding portion MB1 and the MOS transistor connected to the bonding portion MB2. That is, at least one of the gate length or the gate width varies. Both the gate length and the gate width may vary.

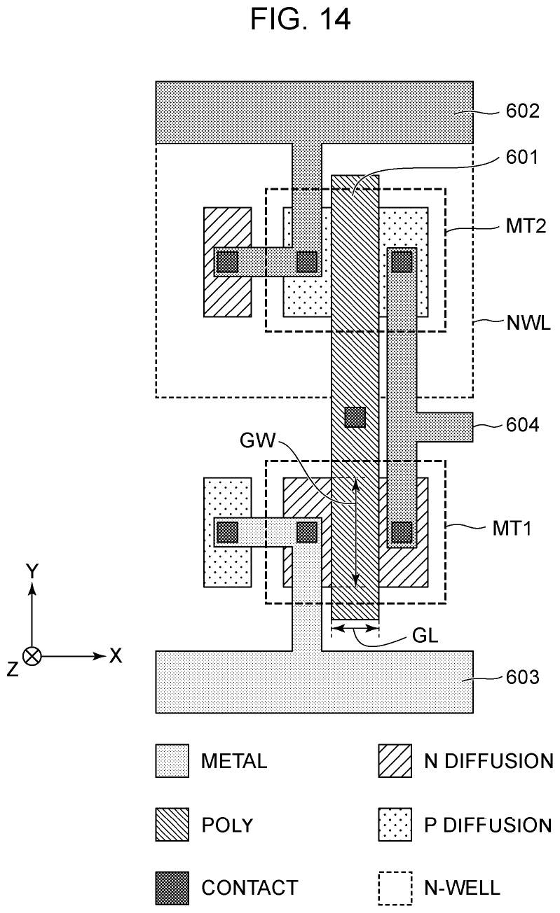

FIG. 14 illustrates a structure, in plan view, of the MOS transistor connected to the bonding portion MB1. In the illustrated configuration, transistors MT1 and MT2 are provided. Herein, in the illustrated example, as transistors being parts of a logic circuit, the transistors MT1 and MT2 forming a NOT gate circuit are provided. The transistors MT1 and MT2 are connected to a common gate electrode 601. However, the NOT gate circuit illustrated herein is an example of the logic circuit, and the present embodiment can also be applied to another logic circuit.

The transistor MT1 is provided in a P-type well region. The transistor MT1 is an N-type transistor the source and the drain of which become an N-type semiconductor region.

One of the source and the drain of the transistor MT1 is connected, through a contact, to power source wiring 603 through which a ground potential (GND potential) is supplied. The other of the source and the drain of the transistor MT1 is connected to output wiring 604 through a contact.

The transistor MT2 is provided in an N-well region NWL. The transistor MT2 is a P-type transistor each of the source and the drain of which becomes a P-type semiconductor region. One of the source and the drain of the transistor MT2 is connected, through a contact, to power source wiring 602 through which the power source voltage VDD is supplied. The other of the source and the drain of the transistor MT2 is connected to the output wiring 604 through the contact.

The transistors M1 and M2 illustrated in FIG. 10, the transistors included in the transistor group MG1, and transistors included in the event detection pixels 813 can be applied as one of the transistors MT1 and MT2 illustrated in FIG. 14. Herein, these transistors are applied as the transistor MT1 for the description. A gate width of the transistor MT1 is a width GW. A gate length of the transistor MT1 is a length GL. The size of a transistor can be recognized as gate width×gate length. Herein, this size is handled as GW×GL.

According to the present embodiment, one of forms listed in Table 1 below can be used. In Table 1, a number in each of the boxes corresponding to columns (1) and (2) indicates the gate width of the transistor, and the gate width of the transistor increases as the number increases. In Table 1, an alphabetic character in each of the boxes corresponding to columns (3) and (4) indicates the gate width of the transistor, and the gate width of the transistor increases as the character becomes closer to Z in alphabetical order. The following combinations Nos. 1 to 6 can be implemented. A drive force of the transistor increases as the gate width of the transistor increases.

TABLE 1

| | (1) | (2) | |
|---|---|---|---|
| | Transistor included in | Transistor included | (3) |
| | MG1 and connected to | in event detection | Transistor |
| Combination | bonding portion MB1 | pixel 813 | M2 |
| No. 1 | 1 | 2 | A |
| No. 2 | 2 | 1 | A |
| No. 3 | 1 | 1 | A |
| No. 4 | 1 | 1 | B |
| No. 5 | 1 | 2 | A |
| No. 6 | 2 | 1 | B |

Herein, the relationships in which the gate width varies between the transistors are described. In contrast, the relationships in which the gate length varies between the transistors may be used. That is, in Table 1 above, the number in each of the boxes corresponding to columns (1) and (2) is related to the gate length of the transistor.

In this case, the gate length of the transistor reduces as the number increases. In Table 1, an alphabetical character in each of the boxes corresponding to columns (3) and (4) is related to the gate length of the transistor. In this case, the gate length of the transistor reduces as the character becomes closer to Z in alphabetical order. The above-described combinations Nos. 1 to 6 can be implemented in such relationships. The drive force of the transistor increases as the gate length of the transistor reduces.

According to the present embodiment, a first conductor and a second conductor are provided. The first conductor is included in the first electrical path and positioned in a predetermined layer between the first surface and the fourth surface. The second conductor is included in the second electrical path and positioned at a predetermined layer. In plan view with respect to the first surface, the planar size varies between the first conductor and the second conductor.

In Nos. 3, 4, 5, and 6 of Table 1 described above, out of the transistors M1 and M2 provided in the semiconductor layer 100 being the predetermined layer between the first surface F1 and the fourth surface F4 illustrated in FIG. 13, one of the transistors M1 and M2 is the first conductor and the other of the transistors M1 and M2 is the second conductor.

Nos. 1, 2, 5, and 6 of Table 1 above is described. Out of a transistor in the transistor group MG1 provided in the semiconductor layer 200 being the predetermined layer between the first surface F1 and the fourth surface F4 illustrated in FIG. 13 and a transistor included in the event detection pixel 813, one of the transistors is the first conductor and the other of the transistors is the second conductor.

Nos. 1, 3, and 5 of Table 1 above are in the form in which the gate width is greater in the transistor related to the output signal of the event detection pixel 813 than in the transistor related to the output signal of the R pixel 810. With this configuration, the output signal of the event detection pixel 813 can be read at high speed. In contrast, Nos. 2, 4, and 6 of Table 1 above are in the form in which the gate width is greater in the transistor related to the output signal of the R pixel 810 than in the transistor related to the output signal of the event detection pixel 813. With this configuration, the output signal of the R pixel 810 can be read at high speed. In a form in which the gate length varies, Nos. 1, 3, and 5 are in the form in which the gate length is smaller in the transistor related to the output signal of the event detection pixel 813 than in the transistor related to the output signal of the R pixel 810. With this configuration, the output signal of the event detection pixel 813 can be read at high speed. Nos. 2, 4, and 6 are in the form in which the gate length is smaller in the transistor related to the output signal of the R pixel 810 than in the transistor related to the output signal of the event detection pixel 813. With this configuration, the output signal of the R pixel 810 can be read at high speed.

Furthermore, both the gate length and the gate width may vary between the transistor related to the output signal of the R pixel 810 and the transistor related to the output signal of the event detection pixel 813. In this case, for example, the drive force of the transistor related to the output signal of the R pixel 810 is set to be higher than the drive force of the transistor related to the output signal of the event detection pixel 813. Thus, the output signal of the R pixel 810 can be read at high speed. Alternatively, the drive force of the transistor related to the output signal of the event detection pixel 813 is set to be higher than the drive force of the transistor related to the output signal of the R pixel 810. Thus, the output signal of the event detection pixel 813 can be read at high speed.

As has been described, the photoelectric conversion device according to the present embodiment can realize signal reading by varying the planar size between the transistor related to the output signal of the event detection pixel 813 and the transistor related to the output signal of the brightness pixel.

### Fourth Embodiment

The photoelectric conversion device according to a fourth embodiment is described. The present embodiment is a form in which the event detection pixel 813 includes an avalanche photodiode (APD).

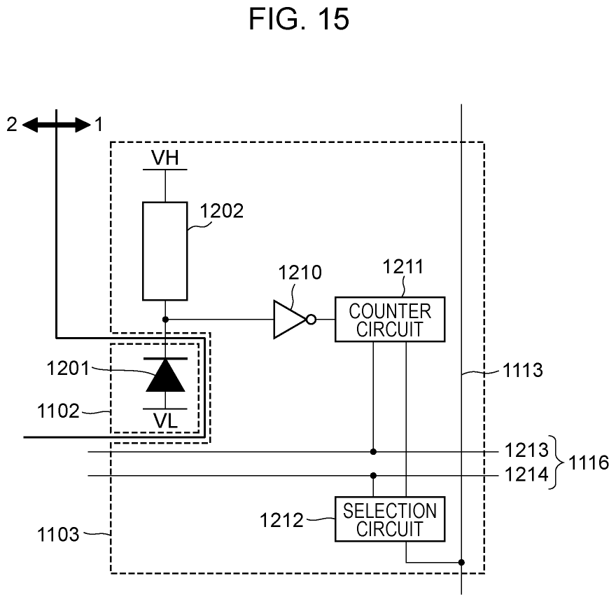

Referring to FIG. 15, a photoelectric conversion element 1102 (corresponding to the event detection pixel 813 illustrated in FIG. 1) including an APD 1201 is provided in the semiconductor component 2, and other members are provided in the semiconductor component 1.

The APD 1201 generates electric charge pairs corresponding to the incident light by using photoelectric conversion. A voltage VL (first voltage) is supplied to the anode of the APD 1201. Furthermore, a voltage VH (second voltage), which is higher than the voltage VL supplied to the anode, is supplied to the cathode of the APD 1201. Such reverse bias voltages that the APD 1201 performs an avalanche multiplication operation are supplied to the anode and the cathode. When a state in which such voltages are supplied is assumed, electric charges generated by the incident light cause avalanche multiplication, and an avalanche current is generated.

When reverse bias voltages are supplied, there are a Geiger mode and a linear mode. In the Geiger mode, operation is performed with a potential difference between the anode and cathode that is greater than a breakdown voltage. In the linear mode, operation is performed with a potential difference between the anode and cathode that is close to the breakdown voltage or smaller than or equal to the breakdown voltage.

An APD operated in the Geiger mode is referred to as a single-photon avalanche diode (SPAD). For example, the voltage VL (first voltage) is-30 V, and the voltage VH (second voltage) is 1 V. The APD 1201 may be operated in the linear mode or the Geiger mode. In the case of the SPAD, the potential difference increases compared to the APD of the linear mode, and a withstanding effect is significant. Accordingly, the SPAD can be used.

A quench element 1202 is connected to the APD 1201 and a power source supplying the voltage VH. The quench element 1202 functions as a load circuit (quench circuit) in signal multiplication due to the avalanche multiplication so as to suppress the voltage supplied to the APD 1201, thereby suppressing the avalanche multiplication (quench operation). Also, the quench element 1202 flows a current corresponding to the voltage drop due to the quench operation so as to return the voltage to be supplied to the APD 1201 to the voltage VH (recharge operation).

A signal processing unit 1103 includes a waveform shaping unit 1210, a counter circuit 1211, and a selection circuit 1212. Herein, it is sufficient that the signal processing unit 1103 include any one of the waveform shaping unit 1210, the counter circuit 1211, and the selection circuit 1212.

The waveform shaping unit 1210 shapes a potential change of the cathode of the APD 1201 obtained when photons are detected, thereby outputting a pulse signal. As the waveform shaping unit 1210, for example, an inverter circuit is used. Although a single inverter is used as the waveform shaping unit 1210 in the example illustrated in FIG. 15, a circuit in which a plurality of inverters are connected in series or another circuit producing a waveform shaping effect may be used.

The counter circuit 1211 counts the pulse signal output from the waveform shaping unit 1210 and holds the count value. When a control pulse pRES is supplied through a drive line 1213, the signal held by the counter circuit 1211 is reset. An event can be detected by using this change in count value. That is, the occurrence of the event can be detected by detecting the change in count value by a predetermined value from the previously held count value.

A control pulse pSEL is supplied from the control unit 803 illustrated in FIG. 1 to the selection circuit 1212 through a drive line 1214 illustrated in FIG. 15, thereby switching electrical connection or disconnection between the counter circuit 1211 and a signal line 1113. The selection circuit 1212 includes, for example, a buffer circuit for outputting signals or the like.

A switch such as a transistor or the like may be disposed between the quench element 1202 and the APD 1201 or between the photoelectric conversion element 1102 and the signal processing unit 1103 so as to switch the electrical connection. Likewise, supply of the voltage VH or the voltage VL supplied to the photoelectric conversion element 1102 may be electrically switched by using a switch such as a transistor.

According to the present embodiment, the configuration using the counter circuit 1211 has been described. Instead of the counter circuit 1211, the photoelectric conversion device may use a time-to-digital converter (TDC) and memory so as to obtain pulse detection timing. At this time, occurrence timing of the pulse signal output from the waveform shaping unit 1210 is converted into a digital signal by the TDC. For measuring the timing of the pulse signal, a control pulse pREF (reference signal) is supplied from the control unit 803 illustrated in FIG. 1 to the TDC through a drive line. The TDC obtains, as a digital signal, a signal obtained when input timing of a signal output from each pixel through the waveform shaping unit 1210 is set as relative time with reference to the control pulse pREF.

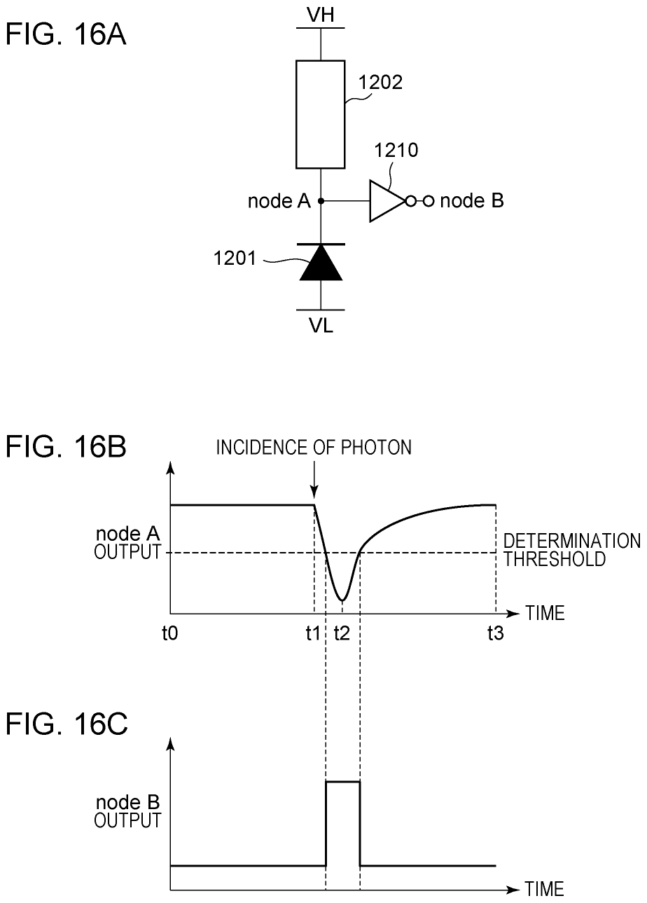

FIGS. 16A to 16C schematically illustrate the relationship between operation of the APD and the output signal.

FIG. 16A is a diagram illustrating the APD 1201, the quench element 1202, and the waveform shaping unit 1210 extracted from FIG. 15. Here, an input side of the waveform shaping unit 1210 is referred to as node A, and an output side of the waveform shaping unit 1210 is referred to as node B. FIG. 16B illustrates a waveform change in node A illustrated in FIG. 16A. FIG. 16C illustrates a waveform change in node B illustrated in FIG. 16A.

In a period between time t0 to time t1, the potential difference of VH-VL is applied to the APD 1201 illustrated in FIG. 16A. When photons are incident upon the APD 1201 at time t1, the avalanche multiplication occurs in the APD 1201, and an avalanche multiplication current flows into the quench element 1202. Thus, the voltage of node A drops. When the amount of the voltage drop further increases and the potential difference applied to the APD 1201 reduces, the avalanche multiplication of the APD 1201 stops as observed at time t2, and a voltage level of node A does not drop further from a certain value. After that, in a period between time t2 and time t3, a current compensating the voltage drop from the voltage VL flows through the node A. At time t3, the voltage level of node A becomes statically determinate at the original potential level. At this time, part of an output waveform exceeding a certain threshold at node A undergoes the waveform shaping in the waveform shaping unit 1210 and is output as a signal by node B.

Thus, as the event detection pixel 813, the pixel including the APD 1201 can be used.

The pixel configuration of the brightness pixels 810 to 812 and the pixel configuration of the event detection pixel 813 may be the same not only in the present embodiment but also in all the embodiments. Regarding the present embodiment, as for the brightness pixels 810 to 812, the form of the photoelectric conversion element 1102 described according to the present embodiment may be used. When the pixel configuration of the brightness pixels 810 to 812 and the pixel configuration of the event detection pixel 813 are the same, allocation of the brightness pixels and the event detection pixel for the pixel array unit 801 can be dynamically changed. That is, a pixel operating as the brightness pixel in a frame operates as the event detection pixel in another frame. This allocation method can be switched depending on whether to prioritize high-speed reading of the event detection pixel as in the first embodiment or signal reading of the brightness pixel as in the second embodiment.

### Fifth Embodiment

According to a fifth embodiment, an embodiment in a laminated sensor including a plurality of semiconductor components is described.

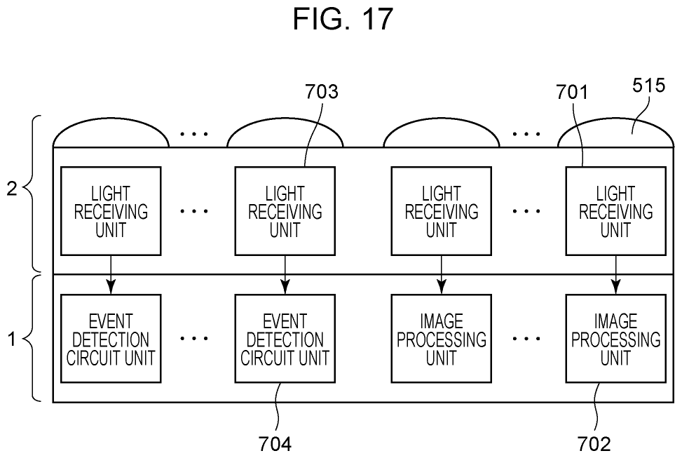

FIG. 17 is a functional block diagram corresponding to the first to fourth embodiments. Referring to FIG. 17, output of light receiving units 703 included in the event detection pixels and provided in the semiconductor component 2 is input to event detection circuit units 704 included in the semiconductor component 1. Furthermore, output of light receiving units 701 included in the brightness pixels and provided in the semiconductor component 2 is input to image processing units 702 provided in the semiconductor component 1. The above-described bonding portions MB1 are provided in the first electrical paths from the light receiving units 701 to the image processing units 702. Furthermore, the above-described bonding portions MB2 are provided in the second electrical paths from the light receiving units 703 to the event detection circuit units 704.

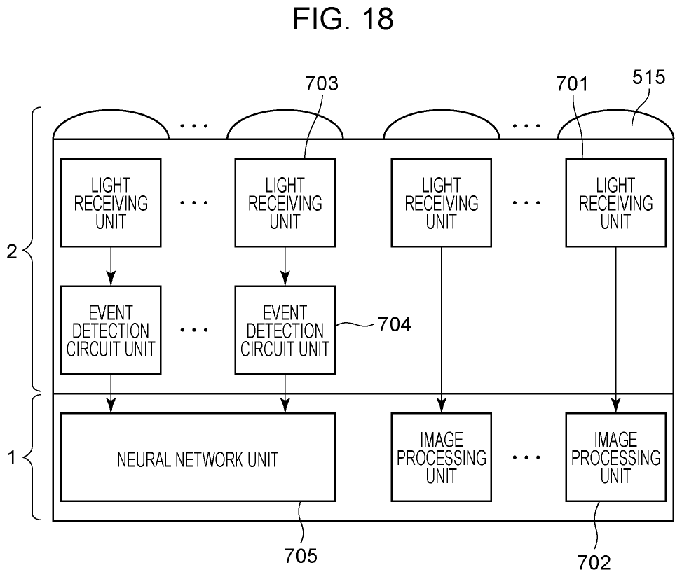

FIG. 18 is a functional block diagram illustrating a form different from the form illustrated in FIG. 17. In a configuration illustrated in FIG. 18, the event detection circuit units 704 are provided in the semiconductor component 2. Furthermore, a neural network unit 705 is provided in the semiconductor component 1. When the event detection circuit units 704 output a digital signal corresponding to a change in the incident light quantity, the neural network unit 705 performs a process of a convolutional neural network (CNN). This digital signal can include a plurality of bits. Meanwhile, when the event detection circuit units 704 output a signal of a spike-shaped waveform corresponding to a change in the incident light quantity, the neural network unit 705 performs a process of a spiking neural network (SNN). The signal of a spike-shaped waveform can be interpreted as a digital signal of a single bit indicating whether a spike wave is generated. The process performed by the neural network unit 705 is not limited to the CNN or the SNN. For example, any of various processes including, for example, a process by a recurrent neural network (RNN) and a process by a long short-term memory (LSTM) can be applied. Instead of the neural network unit 705, a circuit having a pattern recognition processing function may be provided.

In the case of the form illustrated in FIG. 18, the above-described bonding portions MB1 are provided in the first electrical paths from the light receiving units 701 to the image processing units 702. Furthermore, the above-described bonding portions MB2 are provided in the second electrical paths from the event detection circuit units 704 to an element (transistor) included in the neural network unit 705.

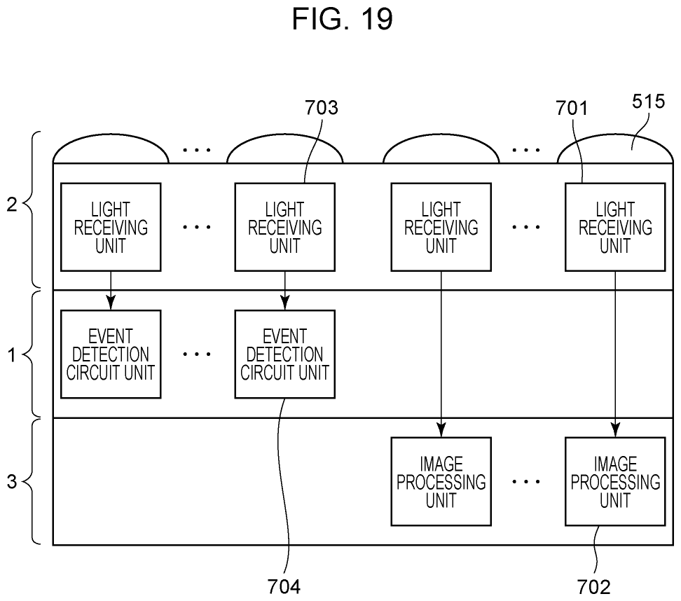

FIG. 19 illustrates a form of a three-layer laminated sensor in which, different from the forms illustrated in FIGS. 17 and 18, three semiconductor components are laminated. The event detection circuit units 704 are provided in the first semiconductor component 1. The light receiving units 703 of the event detection pixels and the light receiving units 701 of the brightness pixels are provided in the second semiconductor component 2. The image processing units 702 are provided in a third semiconductor component 3. The first semiconductor component 1, the second semiconductor component 2, and the third semiconductor component 3 respectively include the first semiconductor layer, a second semiconductor layer, and a third semiconductor layer in this order. Typically, each of the first semiconductor layer, the second semiconductor layer, and the third semiconductor layer are a semiconductor substrate. Although the semiconductor substrate is typically formed of single-crystal silicon, the semiconductor layer may be a chemical-compound semiconductor substrate such as a GaAs substrate.

In the case of this form, typically, the semiconductor component 1 and the semiconductor component 2 are bonded together by using the above-described hybrid bonding. In contrast, the semiconductor component 2 and the semiconductor component 3 are bonded together by bonding only the insulating films together instead of the hybrid bonding. Through electrodes that penetrate through the semiconductor layer (typically the silicon substrate) included in the semiconductor component 1 are used. A process for providing the through electrodes is also referred to as a through silicon via (TSV). The semiconductor component 1 and the semiconductor component 3 are electrically connected to each other by using the through electrodes. Also in the case of this form, the bonding portions MB1 by the hybrid bonding between the semiconductor component 1 and the semiconductor component 2 are provided in the electrical paths between the light receiving units 701 and the image processing units 702. The through electrodes used in the TSV are connected to wiring included in the semiconductor component 2 connected to the bonding portions MB1, and the signals are transmitted to the image processing units 702 provided in the semiconductor component 3 through these through electrodes. Also in this form, it can be said that the above-described bonding portions MB1 are provided in the first electrical paths from the light receiving units 701 to the image processing units 702. Furthermore, the above-described bonding portions MB2 are provided in the second electrical paths from the light receiving units 703 to the event detection circuit unit 704.

Thus, each of the above-described embodiments can be carried out in any of the forms illustrated in FIGS. 17 to 19.

### Sixth Embodiment

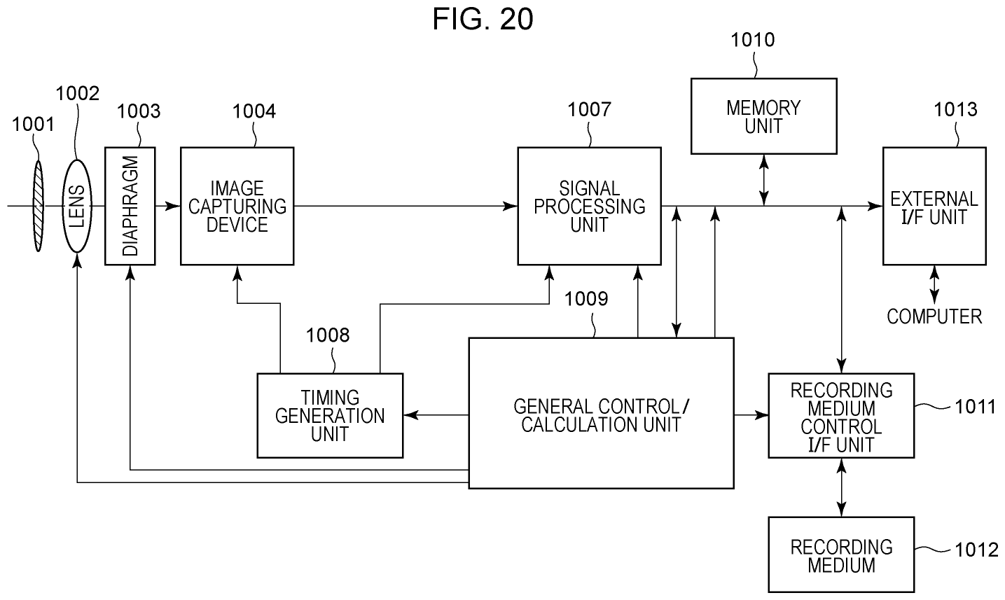

A photoelectric conversion system according to a sixth embodiment is described with reference to FIG. 20. FIG. 20 is a schematic block diagram illustrating a configuration of the photoelectric conversion system according to the present embodiment.

The photoelectric conversion device (image capturing device) described in the first to fifth embodiments can be applied to various photoelectric conversion systems. Examples of the photoelectric conversion systems to which the photoelectric conversion device can be applied include digital still cameras, digital camcorders, surveillance cameras, copiers, facsimile machines, mobile phones, on-vehicle cameras, observation satellites, and so forth. A camera module that includes an optical system such as a lens and the image capturing device is also included in the photoelectric conversion system. FIG. 20 exemplifies a block diagram of a digital still camera as an example of these.

The photoelectric conversion system exemplified in FIG. 20 includes an image capturing device 1004 as an example of the photoelectric conversion device and a lens 1002 configured to form an optical image of a photographic subject in the image capturing device 1004. The photoelectric conversion system also includes a diaphragm 1003 for allowing variation of a light quantity passing through the lens 1002 and a barrier 1001 for protecting the lens 1002. The lens 1002 and the diaphragm 1003 are an optical system that concentrates the light to the image capturing device 1004. The image capturing device 1004 is the photoelectric conversion device (image capturing device) according to any of the above-described embodiments and converts the optical image formed by the lens 1002 into an electric signal.

The photoelectric conversion system also includes a signal processing unit 1007 being an image generation unit configured to generate an image by processing an output signal output from the image capturing device 1004. The signal processing unit 1007 operates to output image data while performing various compensations and compression as required. The signal processing unit 1007 may be formed on a semiconductor substrate in which the image capturing device 1004 is provided or on a different semiconductor substrate from the semiconductor substrate in which the image capturing device 1004 is provided. The image capturing device 1004 and the signal processing unit 1007 may be formed on the same semiconductor substrate.

The photoelectric conversion system further includes a memory unit 1010 for temporarily storing the image data and an external interface unit (external I/F unit) 1013 for communicating with external computer and the like. The photoelectric conversion system further includes a recording medium 1012 such as semiconductor memory for recording or reading image capturing data and a recording medium control interface unit (recording medium control I/F unit) 1011 for recording in or reading from the recording medium 1012. The recording medium 1012 may be incorporated in the photoelectric conversion system or detachably attached to the photoelectric conversion system.

The photoelectric conversion system further includes a general control/calculation unit 1009 that may include one or more processors, circuitry, or combinations thereof and is configured to control various calculations and the entirety of the digital still camera and a timing generation unit 1008 configured to output various timing signals to the image capturing device 1004 and the signal processing unit 1007. Here, a timing signal or the like may be input from the outside, and it is sufficient that the photoelectric conversion system at least include the image capturing device 1004 and the signal processing unit 1007 configured to process the output signal output from the image capturing device 1004.

The image capturing device 1004 outputs the image capturing signal to the signal processing unit 1007. The signal processing unit 1007 performs predetermined signal processing on the image capturing signal output from the image capturing device 1004 and outputs the image data. The signal processing unit 1007 generates an image by using the image capturing signal.

As described above, according to the present embodiment, the photoelectric conversion system to which the photoelectric conversion device (image capturing device) according to any of the above-described embodiments is applied can be realized.

### Seventh Embodiment

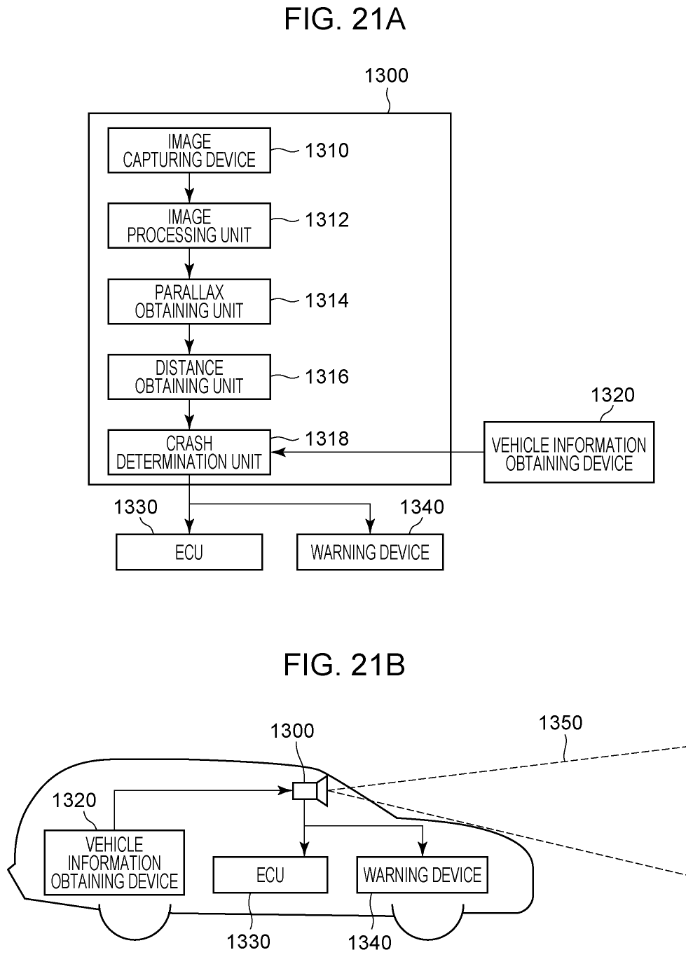

The photoelectric conversion system and a moving body according to a seventh embodiment are described with reference to FIGS. 21A and 21B. FIGS. 21A and 21B respectively illustrate a configuration of the photoelectric conversion system and a configuration of the moving body according to the present embodiment.

FIG. 21A illustrates an example of the photoelectric conversion system related to an on-vehicle camera. A photoelectric conversion system 1300 includes an image capturing device 1310. The image capturing device 1310 is the photoelectric conversion device (image capturing device) according to any of the above-described embodiments. The photoelectric conversion system 1300 includes an image processing unit 1312 and a parallax obtaining unit 1314. The image processing unit 1312 is configured to perform image processing on a plurality of pieces of image data obtained by the image capturing device 1310. The parallax obtaining unit 1314 is configured to calculate a parallax (a phase difference between parallax images) from the plurality of pieces of image data obtained by the photoelectric conversion system 1300. The photoelectric conversion system 1300 also includes a distance obtaining unit 1316 and a crash determination unit 1318. The distance obtaining unit 1316 is configured to calculate the distance to an object based on the calculated parallax. The crash determination unit 1318 is configured to determine whether a possibility of a crash exists based on the calculated distance. Here, the parallax obtaining unit 1314 and the distance obtaining unit 1316 are an example of a distance information obtaining unit configured to obtain information on the distance to the object. That is, the distance information is information related to, for example, the parallax, the amount of defocusing, and the distance to the object. The crash determination unit 1318 may use any of these pieces of the distance information to determine the possibility of a crash. The distance information obtaining unit may be realized by using solely designed hardware or a software module. Alternatively, the distance information obtaining unit may be realized by using a field programmable gate array (FPGA), an application specific integrated circuit (ASIC), or the like or may be realized by using a combination of these.

The photoelectric conversion system 1300, which is connected to a vehicle information obtaining device 1320, can obtain vehicle information such as, for example, a vehicle speed, a yaw rate, and a rudder angle. The photoelectric conversion system 1300 also connected to an electronic control unit (ECU) 1330 being a control device with one or more processors, circuitry, or combinations thereof and configured to output a control signal generating a braking force for a vehicle based on a determination result with the crash determination unit 1318. The photoelectric conversion system 1300 also connected to a warning device 1340 configured to warn a driver based on the determination result with the crash determination unit 1318. For example, when the possibility of a crash is high based on the determination result with the crash determination unit 1318, the ECU 1330 brakes, throttles back, suppresses engine output, or perform other operation to control vehicle for avoiding a crash or reducing damage. The warning device 1340 warns the user by, for example, giving warning with a sound or the like, displaying warning information on a screen of a car navigation system or the like, or applying vibration to a seatbelt or a steering wheel.

According to the present embodiment, an image of a region around the vehicle, for example, a front region or a rear region is captured by the photoelectric conversion system 1300. FIG. 21B illustrates the photoelectric conversion system when the photoelectric conversion system captures an image of a front region of the vehicle (image capturing range 1350). The vehicle information obtaining device 1320 transmits an instruction to the photoelectric conversion system 1300 or the image capturing device 1310. With such a configuration, accuracy of measuring the distance can be improved.

Although the example of the control for avoiding a crash with another vehicle has been explained in the above description, the configuration described above can be applied to control of automatic driving following another vehicle, control of automatic driving so as not to move out of a lane, and the like. Furthermore, the photoelectric conversion system can be applied not only to the vehicle such as an automobile but also to, for example, a moving body (moving device) such as a ship, an aircraft, or an industrial robot. Such a moving body mainly includes either or both of a drive force generation unit configured to generate a drive force utilized to move the moving body and a rotating body utilized to move the moving body. The drive force generation unit can be an engine, a motor, or the like. The rotating body can be a tire, a wheel, a screw propeller of the ship, a propeller of an aircraft, or the like. In addition, the photoelectric conversion system can be applied not only to the moving body but also widely to apparatuses that utilize object recognition such as an intelligent transportation system (ITS) and the like.

### Modifications

The present disclosure is not limited to the above-described embodiment but can be modified in various manners.

For example, the embodiments of the present disclosure include an example in which a subset of configurations of any of the embodiments is added to another embodiment or replaced with a subset of configurations of another embodiment.

The photoelectric conversion system described in the above-described sixth and seventh embodiments is an example of the photoelectric conversion system to which the photoelectric conversion device can be applied. The photoelectric conversion system to which the photoelectric conversion device of the present disclosure can be applied is not limited to the configuration illustrated in FIGS. 13 and 14.

Any of the above-described embodiments represents only examples of embodiments in carrying out the present disclosure, and the technical scope of the present disclosure shall not be limitedly interpreted by these. That is, the present disclosure can be carried out in various forms without departing from the technical concepts or the main features thereof.

The embodiments having been described can be changed as appropriate without departing from the technical thought. The content of the disclosure herein includes not only the description herein but also all the items understandable herein and from the attached drawings. The content of the disclosure herein includes complements of the concepts described herein. That is, when, for example, description to the effect that “A is greater than B” is included herein, this can mean to the effect that “A is not greater than B” is disclosed herein even in the case where description to the effect that “A is not greater than B” is omitted. The reason for this is that, when “A is greater than B” is described to the effect, this description is made on the assumption that the case of “A is not greater thanB” is considered.

With the technique of the present disclosure, forms of electrical paths can be realized in a photoelectric conversion device in which pixels generating signals corresponding to the brightness of incident light and pixels generating event signals are provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-105955, filed Jun. 28, 2023, which is hereby incorporated by reference herein in its entirety.

What is claimed is:

1. A photoelectric conversion device comprising:
a first semiconductor component including
a first semiconductor layer having a first surface that is a light incident surface and a second surface opposite from the first surface, and
a first wiring structure; and
a second semiconductor component including
a second semiconductor layer having a third surface and a fourth surface opposite from the third surface, and
a second wiring structure disposed between the first wiring structure and the third surface,
wherein the first semiconductor layer includes a pixel array unit in which a plurality of first pixels and a plurality of second pixels are disposed, each of the plurality of first pixels being configured to generate a signal corresponding to brightness depending on a light quantity of incident light, and each of the plurality of second pixels being configured to generate an event signal from the incident light,
wherein the photoelectric conversion device includes a first element and a second element, each of the first element and the second element being provided in a semiconductor layer different from the first semiconductor layer,
wherein the first wiring structure includes a first insulating film having a recessed portion, and the second wiring structure includes a second insulating film having a recessed portion,
wherein the photoelectric conversion device includes a first metal portion provided in the recessed portion of the first insulating film and a second metal portion provided in the recessed portion of the second insulating film,
wherein the first insulating film and the second insulating film are bonded to each other at a bonding surface, and the first metal portion and the second metal portion are bonded to each other at the bonding surface,
wherein the first pixel and the first element are connected to each other through a first electrical path that passes through the first metal portion,
wherein the second pixel and the second element are connected to each other through a second electrical path that passes through the second metal portion,
wherein a first conductor and a second conductor are provided, the first conductor being included in the first electrical path and positioned in a predetermined layer between the first surface and the fourth surface, and the second conductor being included in the second electrical path and positioned in the predetermined layer, and
wherein a size of the first conductor and a size of the second conductor are different from each other.

2. The photoelectric conversion device according to claim 1,
wherein the photoelectric conversion device includes a plurality of the first metal portions, and
wherein one of the plurality of first metal portions is the first conductor, and another of the plurality of first metal portions is the second conductor.

3. The photoelectric conversion device according to claim 2,
wherein, in plan view with respect to the first surface, an area of the second conductor is smaller than an area of the first conductor.

4. The photoelectric conversion device according to claim 2,
wherein the first semiconductor component includes an analog-to-digital conversion circuit configured to convert the signals of the plurality of first pixels into digital signals, and
wherein the first metal portions are connected to the analog-to-digital conversion circuit.

5. The photoelectric conversion device according to claim 4,
each of the plurality of second pixels generates a digital signal of a plurality of bits as the event signal.

6. The photoelectric conversion device according to claim 1,
wherein the photoelectric conversion device includes a plurality of the second metal portions, and
wherein one of the plurality of second metal portions is the first conductor, and another of the plurality of second metal portions is the second conductor.

7. The photoelectric conversion device according to claim 6,
wherein the photoelectric conversion device includes a plurality of the first metal portions, and
wherein, out of the plurality of first metal portions, a size of one of the first metal portions bonded to the one of the second metal portions that is the first conductor and a size of another of the first metal portions bonded to the other of the second metal portions that is the second conductor are different from each other.

8. The photoelectric conversion device according to claim 7,
wherein, out of the plurality of first metal portions, a planar size of the one of the first metal portions bonded to the one of the second metal portions that is the first conductor and a planar size of the other of the first metal portions bonded to the other of the second metal portions that is the second conductor are different from each other.

9. The photoelectric conversion device according to claim 6,
wherein, in plan view with respect to the first surface, an area of the second conductor is smaller than an area of the first conductor.

10. The photoelectric conversion device according to claim 6,
wherein the photoelectric conversion device includes a plurality of the first metal portions,
wherein the photoelectric conversion device includes a pad to be connected to an outside of the photoelectric conversion device, and
wherein, in plan view with respect to the first surface, the plurality of first metal portions are disposed in a region between an outer periphery of the pixel array unit and the pad.

11. The photoelectric conversion device according to claim 6,
wherein the photoelectric conversion device includes a plurality of the first metal portions,
wherein the photoelectric conversion device includes a pad to be connected to an outside of the photoelectric conversion device,
wherein the pixel array unit has an opening region upon which the light is incident, and
wherein, in plan view with respect to the first surface, the plurality of first metal portions are disposed in a region between an outer periphery of the opening region and the pad.

12. The photoelectric conversion device according to claim 11,
wherein, in plan view with respect to the first surface, the plurality of second metal portions are disposed at positions superposed on the pixel array unit.

13. The photoelectric conversion device according to claim 6,
wherein, in plan view with respect to the first surface, the plurality of second metal portions are disposed at positions superposed on the pixel array unit.

14. The photoelectric conversion device according to claim 6,
wherein the first metal portion allows a signal output by the first pixel to be transmitted therethrough, and the second metal portions each allow a signal output by a corresponding one of the second pixels to be transmitted therethrough.

15. The photoelectric conversion device according to claim 6,
wherein the first metal portion allows a signal to be input to the first pixel to be transmitted therethrough, and the second metal portions each allow a signal to be input to a corresponding one of the second pixels to be transmitted therethrough.

16. The photoelectric conversion device according to claim 1,
wherein each of the first element and the second element is a metal oxide semiconductor transistor including a gate electrode,
wherein the gate electrode of the metal oxide semiconductor transistor that is the first element is the first conductor, and
wherein the gate electrode of the metal oxide semiconductor transistor that is the second element is the second conductor.

17. The photoelectric conversion device according to claim 16,
wherein, in plan view with respect to the first surface, an area of the second conductor is smaller than an area of the first conductor.

18. The photoelectric conversion device according to claim 1,
wherein, in plan view with respect to the first surface, an area of the second conductor is smaller than an area of the first conductor.

19. The photoelectric conversion device according to claim 1,
each of the plurality of second pixels generates the event signal based on a change in the light quantity of the incident light.

20. The photoelectric conversion device according to claim 19, further comprising:
a neural network unit configured to perform signal processing by using a neural network,
wherein the event signal is input to the neural network unit.

21. The photoelectric conversion device according to claim 20,
wherein the event signal to be input to the neural network unit is a spike-shaped signal.

22. The photoelectric conversion device according to claim 1,
wherein the first element and the second element are provided in the second semiconductor layer.

23. The photoelectric conversion device according to claim 1, further comprising:
a third semiconductor component including a third semiconductor layer,
wherein the second semiconductor component is disposed between the first semiconductor component and the third semiconductor component, and
wherein the second element is provided in the second semiconductor layer, and the first element is provided in the third semiconductor layer.

24. The photoelectric conversion device according to claim 23,
wherein each of the first semiconductor layer, the second semiconductor layer, and the third semiconductor layer is a semiconductor substrate.

25. The photoelectric conversion device according to claim 1,
wherein each of the first semiconductor layer and the second semiconductor layer is a semiconductor substrate.

26. A photoelectric conversion system comprising:
the photoelectric conversion device according to claim 1; and
a signal processing unit configured to process a signal output from the photoelectric conversion device.

27. A moving body comprising:
the photoelectric conversion device according to claim 1; and
a control device configured to control a movement of the moving body.
